(19) United States
(12) Patent Application Publication
(10) Pub. No.: US 2026/0255979 A1
(43) Pub. Date: Aug. 27, 2026

(54) MARKING METHOD AND SEMICONDUCTOR PACKAGE

(71) Applicant: Kioxia Corporation, Tokyo (JP)

(72) Inventor: Kazuki UCHIMURA, Yokohama Kanagawa (JP)

(73) Assignee: Kioxia Corporation, Tokyo (JP)

(21) Appl. No.: 19/238,044

(22) Filed: Jun. 13, 2025

(30) Foreign Application Priority Data
Feb. 26, 2025 (JP) 2025-029091

(51) Int. Cl. H01L 23/544; C23C 22/02; H01L 23/31; H01L 23/552; H01L 25/04; H10B 80/00

(52) U.S. Cl. CPC H10W 46/00; C23C 22/02; H10W 42/20; H10B 80/00; H10W 46/401; H10W 74/117; H10W 90/00; H10W 90/24; H10W 90/752; H10W 90/754

(57) ABSTRACT

A marking method according to the present embodiment includes forming a mark on a metal film formed on a semiconductor package by using a chelation reaction. Forming a mark by using a chelation reaction includes applying a chelating agent to a first region on a first surface of the metal film. The chelating agent is gallic acid.

### CROSS REFERENCE TO RELATED APPLICATIONS

This application is based upon and claims the benefit of priority from the prior Japanese Patent Application No. 2025-029091, filed on Feb. 26, 2025, the entire contents of which are incorporated herein by reference.

### FIELD

The embodiments of the present invention relate to a marking method and a semiconductor package.

### BACKGROUND

With the growing demand for mobile communication terminals due to the spread of 5G, the demand for thin and small-sized electronic component packages (semiconductor packages) is increasing. In addition, with improvement in communication speed, a shield package that is a molded package provided with an optional metal film to prevent electromagnetic wave interference inside and outside a semiconductor package has become increasingly widespread. Moreover, a mark is formed on a semiconductor package to identify the semiconductor package. Semiconductor package marking methods are roughly classified into two kinds: laser marking and ink marking. However, each has drawbacks in ensuring a thin package.

### BRIEF DESCRIPTION OF THE DRAWINGS

FIG. 1 is a cross sectional view illustrating an example of the configuration of a semiconductor device according to a first embodiment;

FIG. 2A is a perspective view illustrating an example of a method for manufacturing the semiconductor device according to the first embodiment;

FIG. 2B is a perspective view illustrating the example of the method for manufacturing the semiconductor device, following FIG. 2A;

FIG. 2C is a perspective view illustrating the example of the method for manufacturing the semiconductor device, following FIG. 2B;

FIG. 3 is a diagram illustrating an example of a chelation reaction according to the first embodiment;

FIG. 4 is a cross sectional view illustrating an example of the configuration of the semiconductor device according to a first comparative example; and

FIG. 5 is a cross sectional view illustrating an example of the configuration of the semiconductor device according to a second comparative example.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A marking method according to the present embodiment includes forming a mark on a metal film formed on a semiconductor package by using a chelation reaction.

### First embodiment

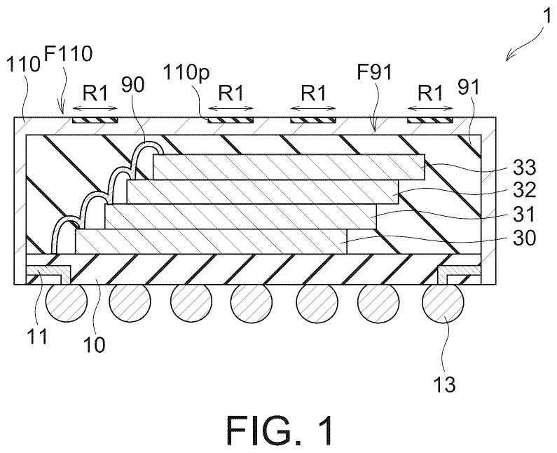

FIG. 1 is a cross sectional view illustrating an example of the configuration of a semiconductor device (semiconductor package) 1 according to a first embodiment. The semiconductor device 1 includes an interconnect substrate 10, semiconductor chips 30 to 33, a bonding wire 90, a sealing resin 91, and a metal film 110. The semiconductor device 1 is, for example, a packaged NAND type flash memory.

The interconnect substrate 10 may be a printed circuit board or interposer including an interconnect layer (not illustrated) and an insulating layer (not illustrated). A low resistance metal such as copper (Cu), nickel (Ni) or an alloy thereof is used as the interconnect layer. An insulating material such as glass epoxy resin is used as the insulating layer. The interconnect substrate 10 may include a multi-layer interconnect structure formed by stacking a plurality of interconnect layers and a plurality of insulating layers. The interconnect substrate 10 may include a penetration electrode penetrating through the front and back surfaces thereof like an interposer.

The interconnect substrate 10 includes a ground line 11. The ground line 11 electrically connects metal bumps 13 provided on a lower surface of the interconnect substrate 10 to the metal film 110. The metal bumps 13 are provided to electrically connect a non-illustrated other component to the interconnect substrate 10.

The semiconductor chip 30 is, for example, a memory chip including a NAND type flash memory. The semiconductor chip 30 is provided with a semiconductor element (not illustrated) on its front surface (upper surface). The semiconductor element may be, for example, a memory cell array and its peripheral circuit (CMOS circuit). The memory cell array may be a stereoscopic memory cell array in which a plurality of memory cells are three-dimensionally disposed. In addition, the semiconductor chip 31 is bonded on the semiconductor chip 30 with a bonding layer (not illustrated) interposed therebetween. The semiconductor chip 32 is bonded on the semiconductor chip 31 with a bonding layer interposed therebetween. The semiconductor chip 33 is bonded on the semiconductor chip 32 with a bonding layer interposed therebetween. Similarly to the semiconductor chip 30, the semiconductor chips 31 to 33 are, for example, a memory chip including a NAND type flash memory. The semiconductor chips 30 to 33 may be identical memory chips. In the diagram, the semiconductor chips 30 to 33 as four memory chips are stacked. However, the number of stacked semiconductor chips may be three or smaller or may be five or larger.

The bonding wire 90 is connected to the interconnect substrate 10 and optional pads of the semiconductor chips 30 to 33. For connection with the bonding wire 90, the semiconductor chips 30 to 33 are stacked with offsets corresponding to the pads.

The sealing resin (resin layer) 91 seals (covered) the semiconductor chips 30 to 33, the bonding wire 90, and the like. Accordingly, in the semiconductor device 1, the plurality of semiconductor chips 30 to 33 are constituted as one semiconductor package on the interconnect substrate 10.

The metal film 110 covers the sealing resin 91. The metal film 110 has an upper surface (surface F110) opposite the sealing resin 91. The metal film 110 is provided on side and upper surfaces of the sealing resin 91.

The metal film 110 is made of, for example, a conductive material such as metal. When the metal film 110 is electrically connected to a ground line of a mounting substrate through the ground line 11 and the metal bumps 13, the metal film 110 functions as a shield film that shields electromagnetic waves.

The metal film 110 contains a first metal element. The first metal element is, for example, iron (Fe) but not limited thereto. The metal film 110 is, for example, stainless steel and includes an alloy of iron (Fe), chromium (Cr), and nickel (Ni) or an alloy of iron (Fe) and chromium (Cr).

The metal film 110 includes a first portion 110p. The first portion 110p is a mark and used, for example, to identify the semiconductor package. The first portion 110p is provided on the front surface (surface F110) of the metal film 110. Specifically, the first portion 110p is provided so as to be exposed in a first region R1 on the upper surface (surface F110) of the metal film 110. The first portion 110p contains a chelation compound of the first metal element. The chelation compound is, for example, iron (III) gallate. Note that, in a case where the metal film 110 contains a plurality of first metal elements, the first portion 110p may contain chelation compounds of the plurality of first metal elements.

Subsequently, a method for forming the first portion 110p of the metal film 110 will be described.

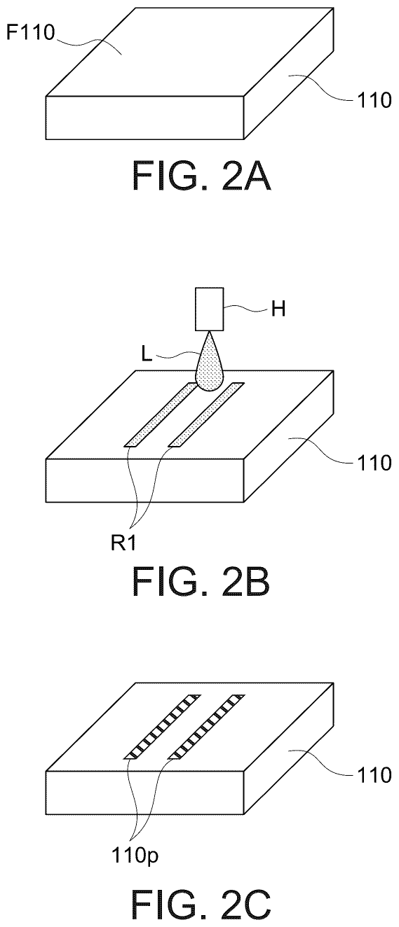

FIGS. 2A to 2C are perspective views illustrating an example of a method for manufacturing the semiconductor device 1 according to the first embodiment.

Note that FIGS. 2A to 2C illustrate processes performed after the metal film 110 illustrated in FIG. 1 is formed. The metal film 110 is formed, for example, by sputtering.

First, as illustrated in FIG. 2A, the surface F110 of the metal film 110 is subjected to pretreatment. This removes oil and an oxide film on the front surface (surface F110) of the metal film 110. After the pretreatment of the surface F110, a mark is formed on the metal film 110 of the semiconductor package by using a chelation reaction.

Subsequently, as illustrated in FIG. 2B, a chemical solution L is applied to the first region R1 on the surface F110. The chemical solution L is, for example, an aqueous solution of a chelating agent. The chelating agent is, for example, gallic acid (tannic acid). The application of the chemical solution L is performed, for example, by an inkjet method. In the example illustrated in FIG. 2B, the chemical solution L is discharged from an inkjet head H. The gallic acid reacts with iron contained in the stainless steel to form a chelate. Iron ions contained in the formed chelation are divalent.

Subsequently, as illustrated in FIG. 2C, the first portion 110p is formed by an oxidation reaction. The oxidation reaction is performed, for example, by air oxidation. As the oxidation reaction progresses, the iron ions change from divalent to trivalent, resulting in formation of a black mark. The first portion 110p contains, for example, iron (III) gallate.

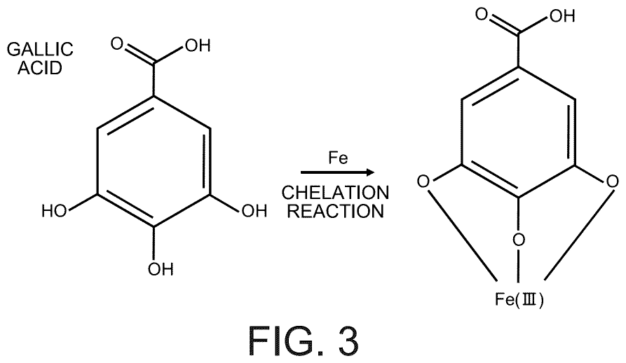

FIG. 3 is a diagram illustrating an example of the chelation reaction according to the first embodiment. FIG. 3 illustrates the chelation reaction between the gallic acid and the iron ions.

The left side of FIG. 3 illustrates the chemical formula of the gallic acid. The right side of FIG. 3 illustrates the structural formula of the iron (III) gallate.

As described above, according to the first embodiment, a mark is formed on the metal film 110 formed on the semiconductor package by using the chelation reaction. In this manner, it is possible to form a mark by treating a metal surface through the chemical reaction, while suppressing the thickness of the semiconductor package.

Note that the chelating agent is not limited to gallic acid. The chelating agent may be, for example, citric acid, ethylenediaminetetraacetic acid (EDTA), diethylenetriaminepentaacetic acid (DTPA), or ethylenediamine-di(o-hydroxyphenylacetic acid) (EDDHA).

Note that the first metal element is not limited to iron. The first metal element may be, for example, chromium (Cr), nickel (Ni), manganese (Mn), copper (Cu), zinc (Zn), or molybdenum (Mo). Moreover, the color of the mark (first portion 110p) may be different in accordance with the first metal element.

Note that the marking method according to the first embodiment is not limited to a shield package but is applicable to any package having a metal surface, such as one in which a heat spreader is disposed on silicon.

### Comparative Example

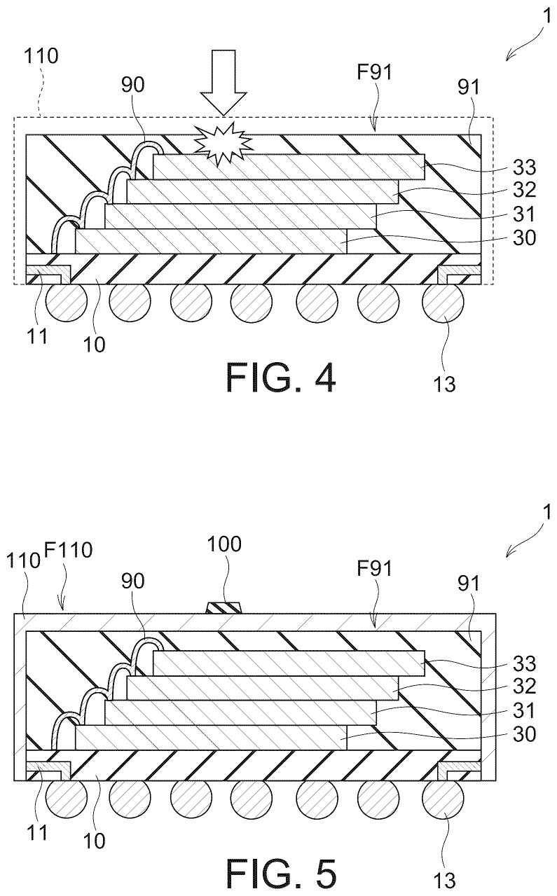

FIG. 4 is a cross sectional view illustrating an example of the configuration of the semiconductor device 1 according to a first comparative example. The first comparative example is different from the first embodiment in that a marking method by laser marking is used.

In the laser marking, a mark is formed by ablating or melting the surface of the sealing resin 91 through irradiation with a laser beam before the metal film 110 is formed.

In the laser marking, it is needed to ensure a certain resin thickness because there is a concern that the laser beam having transmitted through the sealing resin 91 may damage the semiconductor chip 33 or the laser ablation of the sealing resin 91 may expose the bonding wire 90 or the semiconductor chip 33. Specifically, increase in the thickness of the semiconductor package is expected by an amount corresponding to the thickness of the sealing resin 91 between the semiconductor chip 33 or the bonding wire 90 and an upper part of the semiconductor package. Furthermore, the laser marking unavoidably results in CO₂ emission during laser use.

However, in the first embodiment, it is unlikely that the chemical reaction on the surface of the metal film 110 penetrates the metal film 110 or the sealing resin 91 and affects the semiconductor chip 33. Since the chemical reaction does not affect the semiconductor chip 33 in the semiconductor package, the thickness of the semiconductor package can be reduced as compared to the case where the laser marking is used. Moreover, CO₂ emission can be suppressed. In addition, since the processing capability of inkjet is higher than that of laser, the first embodiment in which the chemical solution L is applied by the inkjet method is superior to the laser marking in terms of cost. Unlike the laser marking in which a mark is provided before the metal film 110 as a shield film is formed, a mark is formed after the shield film is formed in the first embodiment. Accordingly, it is possible to uniquely identify the semiconductor package after shielding.

FIG. 5 is a cross sectional view illustrating an example of the configuration of the semiconductor device 1 according to a second comparative example. The second comparative example is different from the first embodiment in that a marking method by ink marking is used.

In the ink marking, there is a concern about increase in the thickness of the ink 100 due to application of an identifiable amount of ink to prevent loss of ink 100 due to physical abrasion, chemically, oil, or the like as well as loss or fading of printing content. Specifically, increase in the thickness of the semiconductor package is expected by an amount corresponding to the thickness of the ink 100 for ensuring visibility. The thickness of the ink 100 is, for example, larger than 15 μm.

However, in the first embodiment, the particle diameter of the gallic acid is smaller than 10 nm, for example. It is easily possible to limit the film thickness of the chelation compound, in other words, increase in the thickness of the semiconductor package, to 3 μm approximately. Thus, in the first embodiment, the thickness of the semiconductor package can be reduced as compared to the ink marking.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A marking method comprising forming a mark on a metal film formed on a semiconductor package by using a chelation reaction.

2. The marking method of claim 1, wherein forming a mark by using a chelation reaction includes applying a chelating agent to a first region on a first surface of the metal film.

3. The marking method of claim 2, wherein the chelating agent is gallic acid.

4. The marking method of claim 2, wherein the chelating agent is applied by an inkjet method.

5. The marking method of claim 3, wherein the chelating agent is applied by an inkjet method.

6. The marking method of claim 1, wherein the metal film contains iron (Fe).

7. The marking method of claim 2, wherein the metal film contains iron (Fe).

8. The marking method of claim 3, wherein the metal film contains iron (Fe).

9. The marking method of claim 4, wherein the metal film contains iron (Fe).

10. The marking method of claim 5, wherein the metal film contains iron (Fe).

11. A semiconductor package comprising a metal film having a first surface and containing a first metal element,
wherein the metal film has a first portion provided on the first surface and containing a chelation compound of the first metal element.

12. The semiconductor package of claim 11, wherein the first metal element is iron (Fe), and the chelation compound is iron (III) gallate.

13. The semiconductor package of claim 11, further comprising:
a semiconductor chip; and
a resin layer covering the semiconductor chip and covered by the metal film,
wherein the first surface is a surface opposite the resin layer.

14. The semiconductor package of claim 12, further comprising:
a semiconductor chip; and
a resin layer covering the semiconductor chip and covered by the metal film,
wherein the first surface is a surface opposite the resin layer.
